(19) United States
(12) Patent Application Publication
(10) Pub. No.: US 2015/0366109 A1
(43) Pub. Date: Dec. 17, 2015

(54) SHIELDING CAGE WITH OVERINSERTION PREVENTION ASPECT

(71) Applicants: Michael K. MCKERVEY, (US); MOLEX INCORPORATED, Lisle, IL (US)

(72) Inventor: Michael K. McKervey, Little Rock, AR (US)

(73) Assignee: Molex Incorporated, Lisle, IL (US)

(21) Appl. No.: 14/761,455

(22) PCT Filed: Jan. 21, 2014
(86) PCT No.: PCT/US2014/012300

§ 371 Date: Jul. 16, 2015

Related U.S. Application Data
(60) Provisional application No. 61/754,212, filed on Jan. 18, 2013.

(51) Int. Cl. H05K 9/00

(52) U.S. Cl. CPC H05K 9/0016

(57) ABSTRACT

A shielding cage is disclosed that has an EMI gasket integrally formed on its exterior. In order to prevent the over-insertion of the cage into a faceplate opening, a plurality of stop members are formed integrally with the cage walls and comprise angled tabs that are bent outwardly away from the cage walls at an angle of between about 30 and 90. The stop members are flanked by a pair of EMI gasket spring fingers and are positioned so that they are located above the centers of modules inserted into module-receiving bays of the shielding cage.

### REFERENCE TO RELATED APPLICATIONS

The Present Disclosure claims priority to prior-filed U.S. Provisional Patent Application No. 61/754,212, entitled “Shielding Cage With Overinsertion Prevention Aspect,” filed on 18 Jan. 2013 with the United States Patent And Trademark Office. The content of the aforementioned Patent Application is incorporated in its entirety herein.

### BACKGROUND OF THE PRESENT DISCLOSURE

The Present Disclosure relates, generally, to shielding cages used for housing electronic modules, and, more particularly, to shielding cages with an integrated aspect that prevents overinsertion of the shielding cage into a faceplate opening.

Shielding cages, whether individually or as a multiple array, are used to provide grounding and shielding to electronic modules inserted into the cages to mate with circuit board-mounted connectors. These cage-connector assemblies are widely utilized in electronic devices, such as servers, routers and switches, and permit the devices to be interconnected to other devices by way of cable assemblies, which include cables that have modules terminated to their opposing ends. The modules may be easily inserted and removed from respective cages. In order to provide access to the cages, the cages typically have their front ends, and associated openings of the cages, oriented to project through a bezel or faceplate.

The cages are mounted to a circuit board, and the front ends thereof usually extend forward over a leading edge of the circuit board. This projecting portion of the cage is inserted into an opening of a faceplate. In some style of shielding cages, an EMI gasket is formed as part of the cage by stamping out a series of spring fingers that make contact with the inner edges of the faceplate opening. In such an integrated gasket style cage, the cage has no means for stopping its insertion length into the faceplate opening. Additional features for stopping the cage with the circuit board or assembly tooling may not be possible due to space constraints. As such, a cage can be pushed too far into the opening; it subsequently must be pulled out and re-inserted. The cage is often unable to be properly re-inserted into the faceplate opening, and the entire cage or cage assembly must be replaced. This delays assembly of the electronic device and increases the cost of the device. A need therefore exists for a shielding cage with a means for preventing the over insertion thereof into a faceplate opening.

The Present Disclosure is therefore directed to an improved shielding cage structure particularly suitable for use in applications wherein the cage has an integrated EMI gasket.

### SUMMARY OF THE PRESENT DISCLOSURE

Accordingly, there is provided an improved shielding cage suitable for integrated gasket applications, which incorporates a stop that prevents the cage from being inserted too far forward into the faceplate opening, thereby reducing the likelihood of damaging cages during their insertion.

In accordance with an embodiment described herein, a shielding cage in accordance with the principles of the Present Disclosure includes a plurality of walls that cooperatively define a hollow interior. The hollow interior may be divided into a plurality of module-receiving bays by respective inner walls, or it may accommodate only one electronic module. The cage walls are stamped near their front end, proximate to the opening of the module-receiving bays, and a plurality of spring fingers are formed on the top and sidewalls of the cage. These spring fingers are cantilevered in nature and extend outwardly from the cage walls and rearwardly toward the rear of the cage. They cooperatively define an integrated EMI gasket in which the spring fingers make contact with the inner surfaces of an electronic device faceplate opening.

The front end of this cage structure is inserted into a faceplate opening and, as such, the spring fingers extend from front to rear in cantilevered fashion. In order to provide a “hard” stop which will prevent overinsertion of the cage structure in the faceplate opening, a series of stop members are formed in the top wall of the cage. Alternatively, the stop members may be formed in the top cover and base of the cage. These stop members are stamped from the top wall (or top cover and base) and extend from rear to front, and terminate in free ends that face in a direction opposite that of the free ends of the EMI gasket spring fingers. Preferably, the stop members are interposed between the spring fingers and there is at least one stop member associated with each cage. Each stop member has a free end and the stop member is bent at an angle with respect to the cage top wall. The stop members should be bent relative to the cage top wall, at an acute angle and preferably between 30-90°, with the most preferable angle being about a 45° or a 90° angle. As such, the stop members firmly engage the rear surface of the faceplate and will not compress or deflect when they make contact with the faceplate.

These and other objects, features and advantages of the Present Disclosure will be clearly understood through a consideration of the following detailed description.

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 is a perspective view of a ganged cage assembly utilizing the hard stop structure according to the Present Disclosure, with the cage assembly mounted to a circuit board and with its front end inserted into a faceplate opening;

FIG. 2 is a perspective view of the cage assembly of FIG. 1;

FIG. 3 is a top plan view of the cage assembly of FIG. 1;

FIG. 4 is a side elevational view of the cage assembly of FIG. 1;

FIG. 5 is an enlarged detail view of a corner of the cage assembly of FIG. 2;

FIG. 6 is an enlarged detail view of a portion of the cage assembly of FIGS. 4; and

FIG. 7 is a perspective view, taken from the rear of the cage assembly of FIG. 1.

### DESCRIPTION OF THE PREFERRED EMBODIMENTS

While the Present Disclosure may be susceptible to embodiment in different forms, there is shown in the Figures, and will be described herein in detail, specific embodiments, with the understanding that the Present Disclosure is to be considered an exemplification of the principles of the Present Disclosure, and is not intended to limit the Present Disclosure to that as illustrated.

As such, references to a feature or aspect are intended to describe a feature or aspect of an example of the Present Disclosure, not to imply that every embodiment thereof must have the described feature or aspect. Furthermore, it should be noted that the description illustrates a number of features. While certain features have been combined together to illustrate potential system designs, those features may also be used in other combinations not expressly disclosed. Thus, the depicted combinations are not intended to be limiting, unless otherwise noted.

In the embodiments illustrated in the Figures, representations of directions such as up, down, left, right, front and rear, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

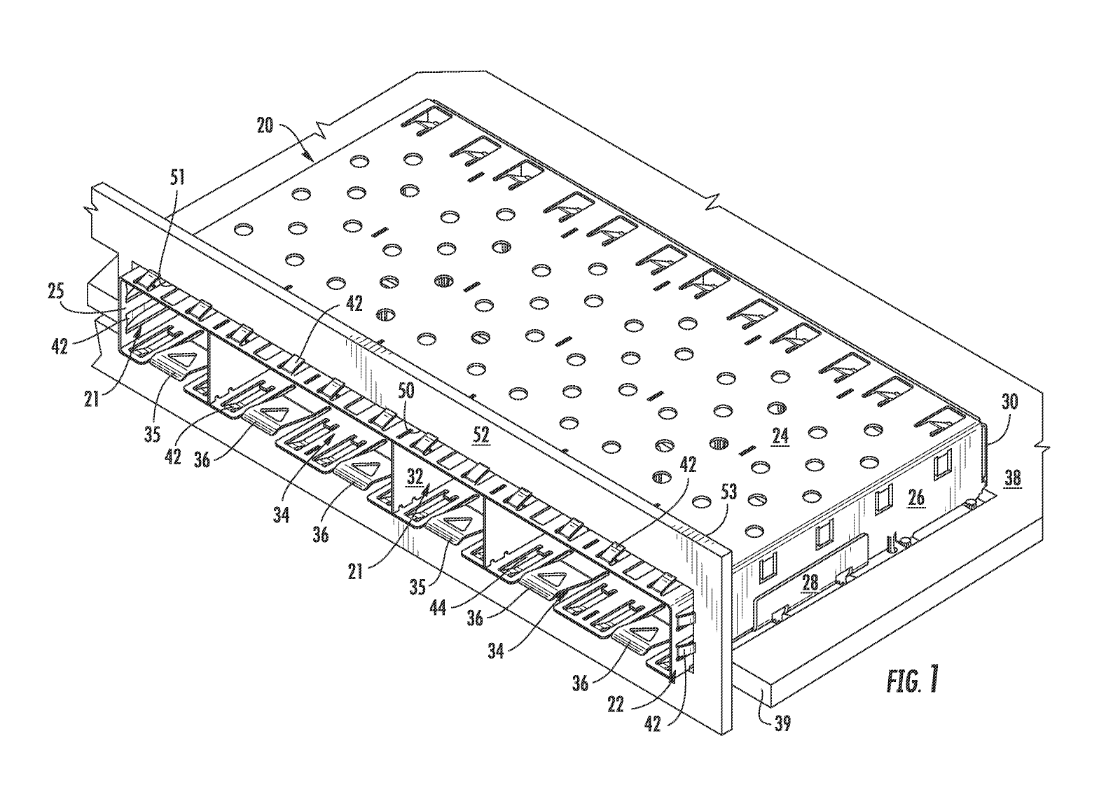

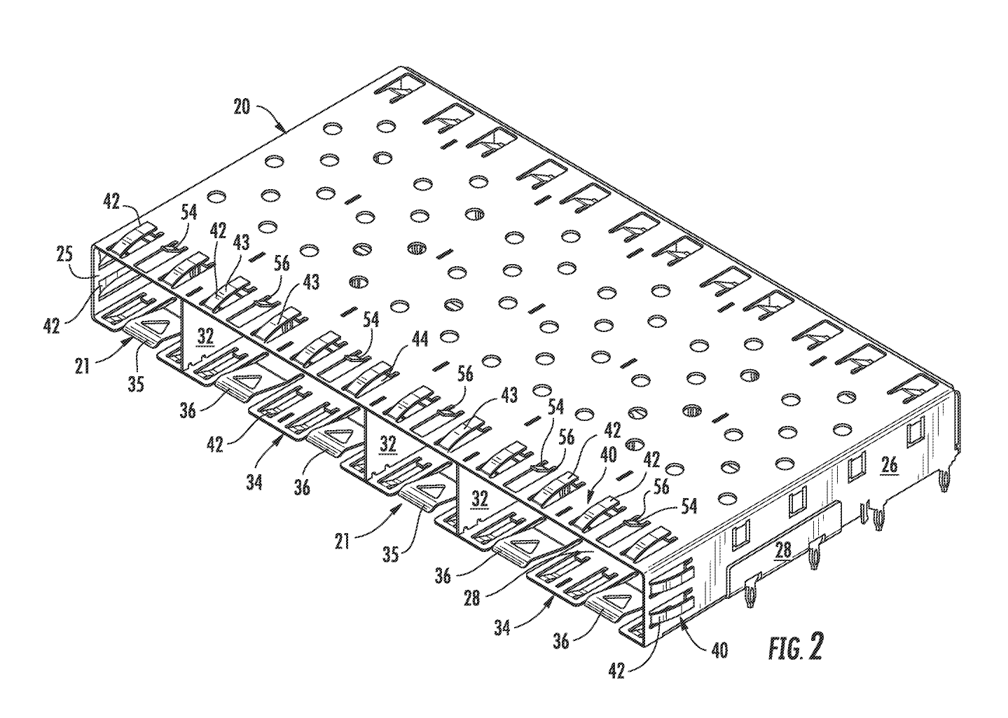

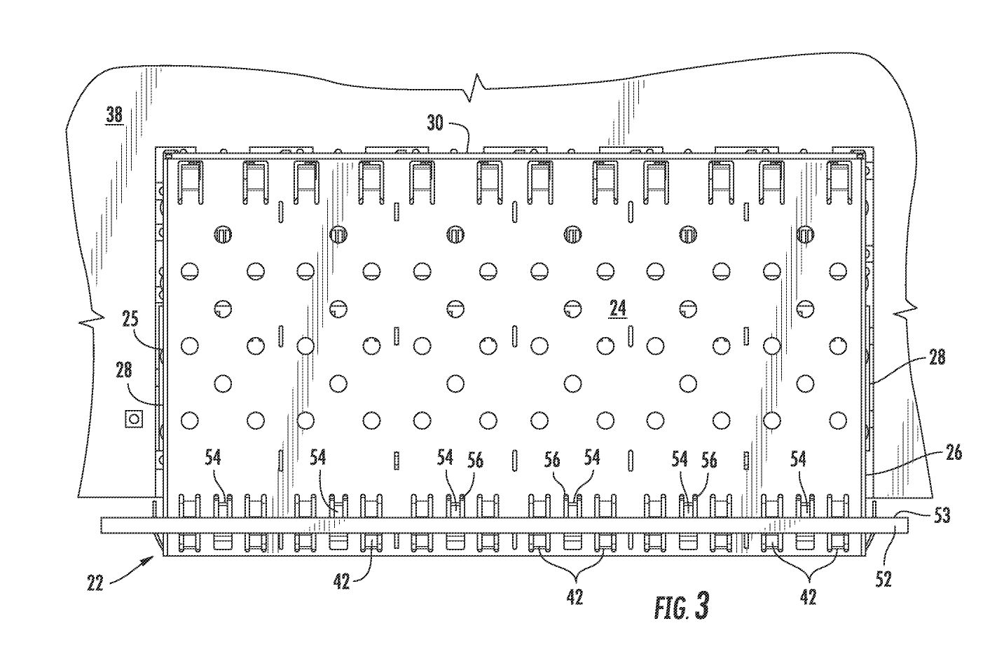

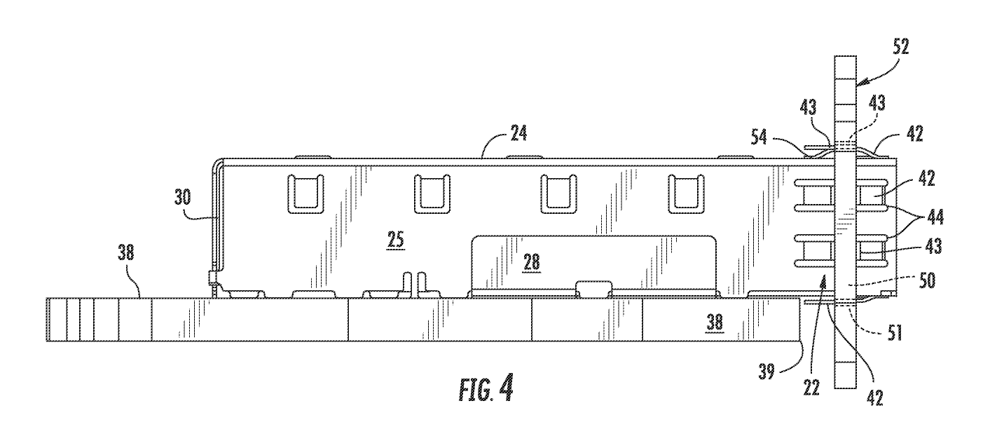

FIG. 1 is a perspective view of a shielding cage assembly 20 constructed in accordance with the principles of the Present Disclosure, The cage assembly 20 is a ganged cage and includes four, distinct hollow bays 21 configured to receive an electronic module (not shown) therein. The cage assembly 20 includes a top wall 24, two side walls 25, 26, a bottom wall 28 and a rear wall 30. Walls 24, 25, 26, 30 may preferably comprise one integral structure, and may be referred to as top cover. Inner walls 32 may be provided which extend between the top and bottom walls 24, 28, and these inner walls 32 divide the interior of the cage assembly into the multiple module-receiving bays 21. As illustrated best in FIG. 2, some of the inner walls 32 of the cage assembly 20 have been removed to define a double-width module-receiving bays 34.

Each bay 21, 34 has a retaining tab 35, 36 associated with it, with one such retaining tab 35 being present in each single bay 21 and two such retaining tabs 36 being present in the double bays 34. These tabs 35, 36 are slightly biased inwardly with respect to their respective cages for contacting a lug formed on a module inserted thereinto.

In order to prevent EMI generated from components on the circuit board 38 to which the cage assembly 20 is mounted, an EMI gasket 40 is provided. The EMI gasket 40 is formed as part of the cage 20 and extends around the perimeter of the front of the cage assembly 20 along the top, side and bottom walls 24-28 thereof. The gasket 40 comprises a plurality of spring contacts that take the form of slender fingers 42 and which have body portions 43 of a cantilevered nature. They are formed by stamping a U-shaped slot 44 and bending the spring fingers 42 outwardly, and in the embodiment illustrated, rearwardly. The spring fingers 42 terminate in free ends 46 and the free ends 46 face the rear of the cage assembly 20.

The cage assembly 20 is normally inserted into an opening 50 of a faceplate 52 of an electronic device. The front ends 22 of the cages of the assembly 20 extend forward past the front edge 39 of the circuit board 38 and are inserted into the faceplate opening 50. Consequently, the body portions 43 of the spring fingers 42 make contact with the inner surfaces 51 of the faceplate opening 50, providing a plurality of grounding contact points that provide an EMI barrier, which substantially prevents the emission of EMI from the device.

In assembly of the electronic device in which the cage assembly 20 is used, the front ends 22 of the cages 20 are provided with a plurality of stop members 54 defined in the cage sidewalls. The stop members 54 may be formed by stamping them from the cage sidewalk via U-shaped slots 56. The stop members 54 are then bent outwardly (upwardly as illustrated in the Figures) at an acute angle to the cage sidewalls. It is desirable that the acute angle have a value of between about 30-90°, as angles within this range are not too shallow or great so as to result in the stop member 54 contact with the faceplate 52 placing excessive stress on the stop members 54 thereby resulting in bending or compression thereof, The most preferred angle is about 45°, although 90° is surely contemplated. The stop members can best be described as square or rectangular tabs that extend forwardly, opposite to the spring fingers which extend rearwardly. However, in an alternative embodiment, the stop members may extend from a side of the slot (in this case, the U-shape of the slot would not be open towards rear of the cage, but rather toward one side thereof, and the rectangular tabs would extend to the side). Both the gasket spring fingers 42 and the stop members 54 have free ends that extend in opposite directions.

The stop members 54 provide a plurality of individual contact points that bear against the rear surface 53 of the faceplate 52, and serve to stop any further forward movement of the cage front end 22 within the faceplate opening 50. At least one stop member 54 is associated with each module-receiving bay 21, 34, and in double bays 34, at least two stop members 54 are provided, with each stop member disposed on the cage wall 24 generally centered above its respective module. Hence, as shown in FIGS. 1-2, there is one stop member 54 associated with each of the two single module-receiving bays 21 and two stop members 54 associated with each of the double module-receiving bays 34.

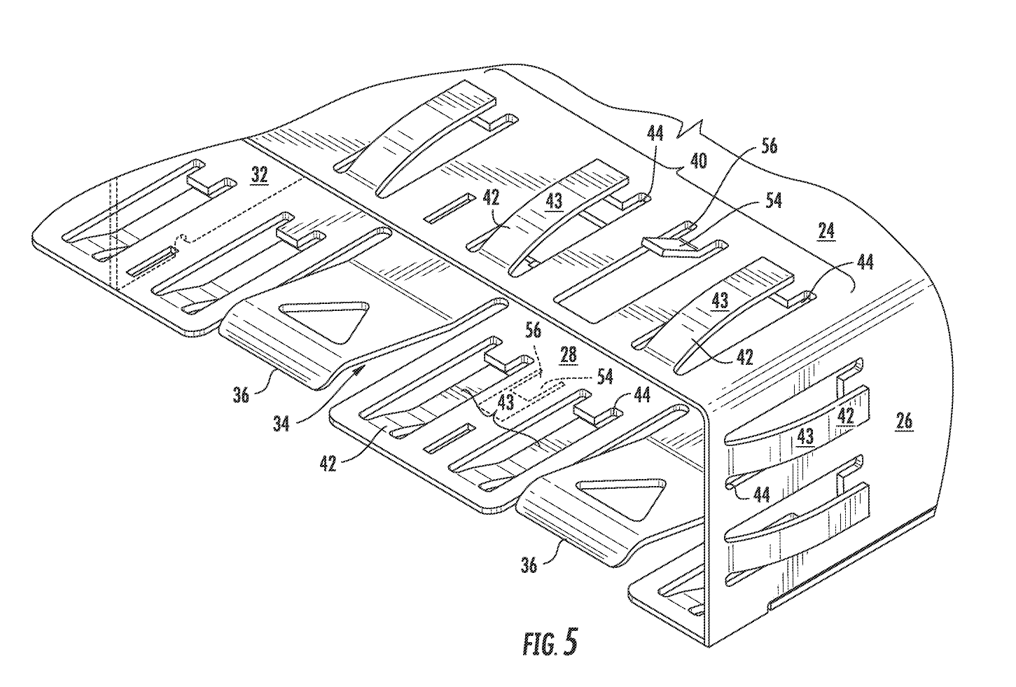

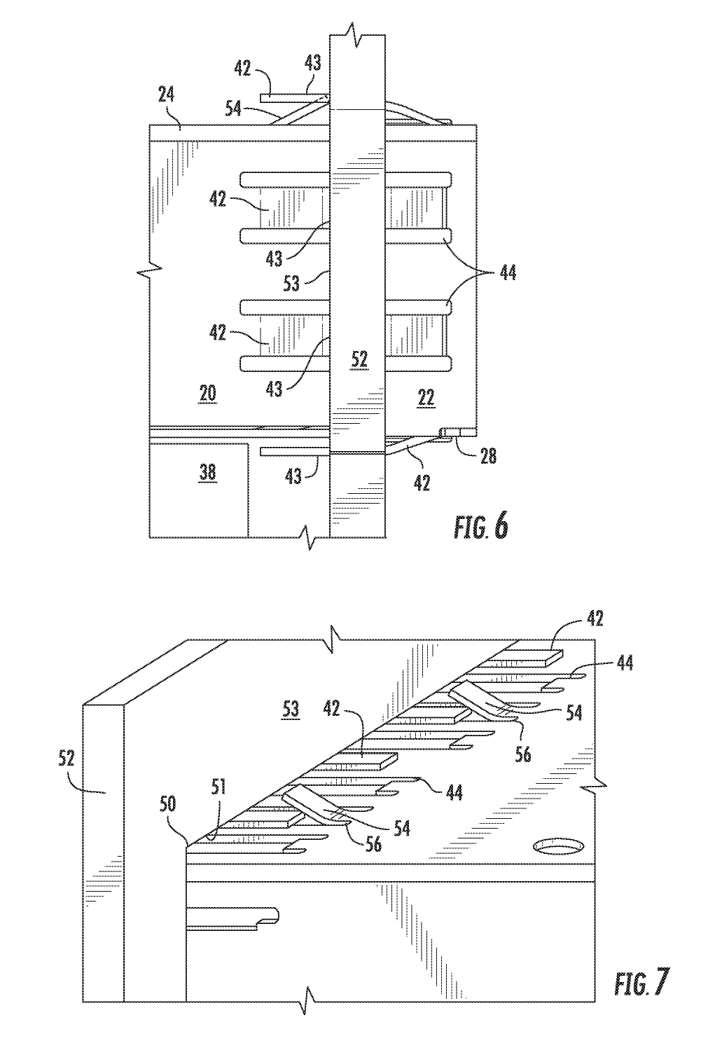

In FIGS. 1-2, the stop members 54 are shown disposed on the cage top wall 24 along an imaginary lined defined by the EMI gasket spring fingers 42, Each stop member 54 is preferably interposed between a pair of gasket spring fingers 42. The stop members may also be formed on the cage sidewalls 25, 26 or in the bottom wall 28 as indicated in phantom in FIG. 5, and have a length that does not exceed on-half the length of the gasket spring fingers 42, and preferably is about one-third the length of the EMI gasket spring fingers 42.

While a preferred embodiment of the Present Disclosure is shown and described, it is envisioned that those skilled in the art may devise various modifications without departing from the spirit and scope of the foregoing Description and the appended Claims.

What is claimed is:

1. A shielding cage for housing an electronic module, the cage comprising:
at least top and sidewalk cooperatively defining a hollow enclosure;
a front end, the front end having an opening that permits insertion and removal of a module therefrom, the front end being configured for partial insertion into an opening of a respective faceplate;
an EMI gasket formed from the cage top and sidewalls, the EMI gasket including a plurality of individual cantilevered spring fingers formed from the cage, each spring finger extending outwardly from and along the respective top and sidewalls in a position for contacting the opening of the faceplate; and
a plurality of stop members, each stop member being formed in the cage and disposed on the cage within the EMI gasket, each stop member being interposed between pairs of spring fingers.

2. The shielding cage of claim 1, wherein each stop member extends along the cage in a first direction.

3. The shielding cage of claim 2, wherein each spring finger extends along the cage in a second direction.

4. The shielding cage of claim 3, wherein the first direction is opposite to the second direction.

5. The shielding cage of claim 1, wherein each stop member extends outwardly from the cage at an angle.

6. The shielding cage of claim 5, wherein the angle is between about 30 and 90°.

7. The shielding cage of claim 5, wherein the angle is about 45°.

8. The shielding cage of claim 5, wherein the angle is about 90°.

9. The shielding cage of claim 1, wherein each spring fingers and each stop members has free ends.

10. The shielding cage of claim 1, wherein the spring finger free ends face rearwardly and the stop member free ends face forwardly.

11. The shielding cage of claim 1, further including a plurality of module-receiving bays, each stop member associated with one of the module-receiving bays.

12. The shielding cage of claim 11, wherein each stop member is disposed on the cage wall above a centerline of a module inserted into the cage.

13. The shielding cage of claim 1, wherein each stop member is formed in the cage top wall.

14. The shielding cage of claim 1, wherein each stop member has a length of about one-third a length of the spring fingers.

15. A shielding cage for housing an electronic module, the cage comprising:
at least top and sidewalk that cooperatively define a hollow interior;
a front end, the front end having an opening that permits insertion and removal of an electronic module therefrom, the front end being configured for partial insertion into an opening of a respective faceplate;
an EMI gasket integrally formed from the top and sidewalk, the EMI gasket including a plurality of individual cantilevered spring fingers, each spring finger extending outwardly from and along the top and sidewalk in position for contacting the faceplate opening; and
a plurality of stop members integrally formed therefrom and disposed proximate to the EMI gasket, each stop member including a tab bent outwardly at an angle to the cage, each stop member being associated with a respective module inserted into the cage;
wherein each stop member extends along the cage in a first direction and each spring fingers extends along the shielding cage in a second direction.

16. The shielding cage of claim 15, wherein the angle is between about 30 and 90°.

17. The shielding cage of claim 16, wherein the tab has a length not greater than about one of the length of one spring finger.

18. The shielding cage of claim 15, wherein each stop member is interposed between two spring fingers.

19. The shielding cage of claim 15, wherein each spring fingers and each stop members has free ends.

20. The shielding cage of claim 19, wherein the spring finger free ends face rearwardly and the stop member free ends face forwardly.
